(19) United States
(12) Patent Application Publication
(10) Pub. No.: US 2019/0005906 A1
(43) Pub. Date: Jan. 3, 2019

(54) DISPLAY PANEL AND DISPLAY APPARATUS

(71) Applicants: HKC Corporation Limited, Shenzhen (CN); Chongqing HKC Optoelectronics Technology Co., Ltd., Chongqing (CN)

(72) Inventor: YU-JEN CHEN, Chongqing (CN)

(21) Appl. No.: 15/744,826

(22) PCT Filed: Mar. 27, 2017
(86) PCT No.: PCT/CN2017/078271

§ 371 Date: Jan. 15, 2018

(30) Foreign Application Priority Data
Nov. 11, 2016 (CN) 2016109975862

(51) Int. Cl. G09G 3/36; G02F 1/1333; H05K 1/18; G02F 1/1362

(52) U.S. Cl. CPC G09G 3/3648; G02F 1/133305; G09G 2310/08; G02F 1/136286; H05K 1/189

(57) ABSTRACT

The present application discloses a display panel and a display apparatus. The display panel includes an array substrate, at least two source driver ICs and a timing control board. The at least two source driver ICs are spacedly arranged on one side surface of the array substrate, a timing controller is disposed on the timing control board, at least one of the source driver ICs is wirelessly connected to the timing controller, and a length of the timing control board is less than a maximum distance across all the source driver ICs.

### TECHNICAL FIELD

The present application relates to the technical field of displays, and particularly relates to a display panel and a display apparatus.

### BACKGROUND

Liquid crystal display apparatuses have numerous advantages, such as a thin body, power saving, no radiation, etc., and are widely used. Most liquid crystal display apparatuses in the current market are backlit liquid crystal display apparatuses, each including a liquid crystal panel and a backlight module. Working principle of the liquid crystal panel is that liquid crystals are put in two parallel glass substrates, and a driving voltage is applied to two glass substrates to control rotational direction of the liquid crystals, to refract light rays of the backlight module to generate a picture.

Thin film transistor liquid crystal display apparatuses (TFT-LCD apparatuses) currently maintain a leading status in the display field because of low power consumption, excellent picture quality, high production yield, and other properties. Similarly, the TFT-LCD apparatus comprises a liquid crystal panel and a backlight module. The liquid crystal panel comprises a color filter substrate (CF substrate) and a thin film transistor substrate (TFT substrate), and transparent electrodes on relative inner sides of the above substrates. A layer of liquid crystals (LCs) is positioned between two substrates. The liquid crystal panel changes a polarized state of light by controlling direction of the LCs through an electric field, for penetration and obstruction of a light path via a polarized plate to display.

Specific to a television liquid crystal display apparatus (TV LCD apparatus), the TV LCD apparatus has been developed for decades so far. In the prior art, driving manner of the liquid crystal panel is low-voltage differential signaling (LVDS) and power signals are input into a system end. The above signals are converted into mini-LVDS and various DC (direct current) voltage sources through a timing control board, and transmitted to a source driver IC (integrated circuit) and a gate driver IC. Finally, voltage driving TFT required for driving a TFT panel is produced and then a picture is generated. With the development of science and technology, the panels have a higher and higher resolution. More and more source driver ICs are required to drive one liquid crystal panel. For example, four source driver ICs are required at high definition (HD) (1366X768) resolution, wherein the four source driver ICs are dispersed on a single edge of an array substrate in the liquid crystal panel in equal proportions, or the four source driver ICs are spacedly arranged on a single edge of the array substrate. The mini-LVDS generated by the timing control board is transmitted to the source driver ICs through a printed circuit board (PCB) and a chip on film (COF, or called flexible circuit board). Length of the PCB is set under coordination with the four source driver ICs to connect with the four source driver ICs simultaneously, so that the PCB (or the timing control board) must be long enough.

However, if the timing control board is too long and too large, it causes waste of the boards, and if the timing control board is too long and too large, great inconvenience is generated for engineers in the production and design process. The engineers need to redesign the circuits according to size of the timing control board, and meanwhile, difficulty is also generated for purchase, causing increase of production processes.

### SUMMARY

A technical problem to be solved by the present application is to provide a display panel, to reduce a size and facilitate alignment bonding.

In addition, the present application further provides a display apparatus which adopts the display panel.

The purpose of the present application is achieved through the following technical solution.

According to one aspect of the present application, the present application discloses a display panel comprising:

an array substrate;

at least two source driver ICs spacedly arranged on one side surface of the array substrate; and

a timing control board disposed on the timing control board, wherein at least one of the source driver ICs is wirelessly connected to the timing controller, and length of the timing control board is less than a maximum distance across all the source driver ICs.

The timing controller is wirelessly connected to all the source driver ICs directly. The timing controller is wirelessly connected to all the source driver ICs directly, so that the size of the timing control board is greatly reduced without wiring on the timing control board in a signal transmission process of the timing controller with the source driver IC. Because of this, the present application well saves boards, more facilitates the purchase and the design of circuits by engineers, and well saves production processes by greatly reducing the size of the timing control board.

In addition, if the timing control board is too long and too large, serious expansion and extraction are often caused because the timing control board is damped when an LCD Module (LCM) is connected to the flexible circuit board and the timing control board. Therefore, normal alignment cannot be performed generally during butting, causing great inconvenience for production. However, all the source driver ICs and the timing controller in the present application are wirelessly connected. Because of this, the size of the timing control board is greatly reduced, and serious expansion and extraction date to the damped overlarge timing control board may not appear, thereby realizing normal alignment and normal fixed bonding of the timing control board.

The display panel further comprises at least two flexible circuit boards spacedly arranged. The two flexible circuit boards are fixedly bonded to the array substrate. One of the source driver ICs is disposed on one of the flexible circuit boards. The flexible circuit board comprises a first flexible circuit board. The source driver IC comprises a first source driver IC. The first source driver IC is disposed on the first flexible circuit board, and the timing control board is coupled to the array substrate through the first flexible circuit board. Compared with the prior art, the timing control board needs to be fixedly bonded to all the flexible circuit boards and the timing controller penetrates through all the flexible circuit boards and is connected to all the source driver ICs through the signal line, the present application just enables the timing control board and the first flexible circuit board to be fixedly bonded, thereby not only greatly reducing the size of the timing control board, but also greatly saving a bonding relationship between the timing control board and the flexible circuit board, and also greatly saving time in a practical processing and production process.

The display panel further comprises a power module, and the power module is electrically connected to the source driver IC through the power line. In the present application, because the timing controller on the timing control board can be wirelessly connected to all the source driver ICs, the installation and fixation scope of the timing control board is very wide. Thus, the power module may not be disposed on the timing control board. For example: the power module is directly disposed on a glass plate of the array substrate, and the power line is also disposed on the glass plate of the array substrate. Because of this, the power module can be electrically connected to the source driver IC directly through the power line on the array substrate.

The power module is disposed on the timing control board. The timing control board is fixedly connected to the first flexible circuit board directly, and the power module is disposed on the timing control board, to facilitate the electrical bonding with the first source driver IC and other source driver ICs.

The power line comprises a first power line, a second power line and a third power line. The power module is directly connected to the first source driver IC through the first power line. A first end of the second power line is connected to the power module, and a second end of the second power line is connected to the third power line. The second power line penetrates through the first flexible circuit board; the third power line is disposed on the array substrate. The third power line is connected to at least one of the source driver ICs. This is a specific manner of the power module is electrically connected to the source driver IC through the power line. The power module cannot directly realize electrical bonding with all the source driver ICs through the wiring of the timing control board, because the timing control board is fixedly bonded to the first flexible circuit board, the first source driver IC is disposed on the first flexible circuit board and the power module can be directly connected to the first source driver IC through the first power line, and also because the timing control board is only fixedly connected to the first flexible circuit board and not fixedly connected to all the flexible circuit boards. In the present application, the third power line is disposed on the glass plate of the array substrate to realize electrical bonding with the source driver IC, and is connected to the second power line to realize a communication relationship of the entire electrical bonding. The third power line occupies a small space, and may not produce large parasitic capacitance and resistance. Therefore, the third power line can be disposed on the array substrate.

The power line comprises a fourth power line and a fifth power line. A first end of the fourth power line is connected to the power module, and a second end of the fourth power line is connected to the fifth power line. The fourth power line penetrates through the first flexible circuit board. The fifth power line is disposed on the array substrate. The fifth power line is connected to all the source driver ICs. This is another specific manner of the power module is electrically connected to the source driver IC. Specifically, one end of the fourth power line is led out of the power module. Then the fourth power line penetrates through the entire first flexible circuit board and is connected to the fifth power line on the array substrate. The fifth power line is electrically connected to all the source driver ICs. Because of this, the power module realizes an electrical bonding relationship with all the source driver ICs. Compared with the electrical bonding realized by the first power line, the second power line and the third power line, the present application occupies more array substrate spaces through the fourth power line and the fifth power line.

The power line comprises a sixth power line and a seventh power line. The power module is electrically connected to the first source driver IC directly through the sixth power line. The power module is electrically connected to at least one of the source driver IC through the seventh power line. The sixth power line and the seventh power line are not disposed on the array substrate. Because of this, this is another specific manner of the power module realizes electrical bonding with the source driver IC.

The source driver IC comprises a first source driver IC. The timing control board is electrically connected to the first source driver IC. The first source driver IC is positioned between the array substrate and the timing control board. The timing controller is connected to the first source driver IC through a signal line. Because the first source driver IC is positioned between the timing control board and the array substrate, and the timing control board is close to the first source driver IC, bonding between the timing controller and the first source driver IC through the signal line is convenient without any additional increasing the size of the timing control board. This is another manner of the timing controller is electrically connected to the source driver IC in the present application. Compared with the wireless bonding between the timing controller and all the source driver ICs, the present application adds the signal line for the timing control board.

The source driver IC comprises a first source driver IC and a second source driver IC. The timing control board is electrically connected to the first source driver IC and the second source driver IC. The first source driver IC and the second source driver IC are positioned between the timing control board and the array substrate. The timing control board is coupled to the first source driver IC through a first signal line, and the timing control hoard is coupled to the second source driver IC through a second signal line. Because the first source driver IC and the second source driver IC are positioned between the timing control board and the array substrate, and the timing control board is close to the first source driver IC and the second source driver IC, bonding of the timing controller with the first source driver IC and the second source driver IC through the first signal line and the second signal line is convenient without any additional increasing the size of the timing control board.

It should be noted that the signal lines cannot be disposed on the array substrate in the present application. A line of the glass plate on the array substrate has large parasitic resistance and capacitance. Signals (e.g.: mini-LVDS high-frequency signals) carried by the signal lines cannot be transmitted.

The wireless bonding comprises any one below: Bluetooth, WIFI, 2.4G radio, Radio Frequency (RF) and Near Field Communication (NFC).

According to another aspect of the present application, the present application further discloses a display apparatus comprising the above display panel.

If the signal lines and the power line are disposed on the timing control board, and the timing control board realizes electrical bonding with the source driver ICs through the signal line and further realizes signal transmission, then the tiring control board has a large volume and needs to consume more boards, causing a waste. Moreover, the large timing control board needs more processing procedures, bringing inconvenience for purchase and production. In addition, when the timing control board is installed, serious expansion and extraction are often caused because the overlarge timing control board is damped, and normal alignment often cannot be performed during bonding. When the timing control board in the display panel of the present application is electrically connected to or is in the signal transmission process with the source driver IC, at least one of the source driver ICs is wirelessly connected to the timing control board to realize wireless signal transmission. Because of this, fewer signal lines (part of the source driver ICs are connected to the timing control board through the signal line to realize signal transmission) or no signal line can be disposed on the timing control board. Then, the size of the timing control board is reduced, so that a length of the timing control board is less than a maximum distance across all the source driver ICs, thereby ensuring that the timing control board can complete signal transmission without aligning with all the source driver ICs. The present application well not only saves boards, but also facilitates the purchase and the design of circuits by engineers, and saves production processes by reducing the size of the timing control board.

Specifically, for example: If the number of the source driver ICs is two, then the timing control board can be wirelessly connected to two source driver ICs simultaneously; or the timing control board is wirelessly connected to one source driver IC, and is in wired bonding with the other source driver IC.

For another example: If the number of the source driver ICs is three, then the timing control board can be wirelessly connected to three source driver ICs simultaneously; or the timing control board is wirelessly connected to one source driver IC, and is in wired bonding with the other two source driver ICs; or the timing control board is wirelessly connected to two source driver ICs, and is in wired bonding with the other source driver IC.

For another example: If the number of the source driver ICs is four, then the timing control board can be wirelessly connected to four source driver ICs simultaneously; or the timing control board is wirelessly connected to one, two or three source driver ICs, and is in wired bonding with the remaining other source driver ICs. When the number of the source driver ICs is greater than four, the manner that all the source driver ICs are wirelessly connected can be adopted, or the manner that only part of the source driver ICs are wirelessly connected is adopted.

### DESCRIPTION OF THE DRAWINGS

The drawings included are used for providing further understanding of embodiments of the present application, constitute part of the description, and are used for illustrating implementation manners of the present application, and interpreting principles of the present application together with text description. Apparently, the drawings in the following description are merely some embodiments of the present application, and for those ordinary skilled in the art, other drawings can also be obtained according to the drawings without contributing creative labor. In the drawings:

FIG. 1 is a structural schematic diagram of a display panel.

FIG. 2 is a structural schematic diagram of a display panel of an embodiment of the present application.

FIG. 3 is a structural schematic diagram of a display panel of an embodiment of the present application.

FIG. 4 is a structural schematic diagram of display panel of an embodiment of the present application.

FIG. 5 is a structural schematic diagram of a display panel of an embodiment of the present application.

FIG. 6 is a structural schematic diagram of a display panel of an embodiment of the present application.

FIG. 7 is a structural schematic diagram of a display panel of an embodiment of the present application.

FIG. 8 is a structural schematic diagram of a display panel of an embodiment of the present application.

FIG. 9 is a structural schematic diagram of a display panel of an embodiment of the present application.

FIG. 10 is a structural schematic diagram of a display panel of an embodiment of the present application.

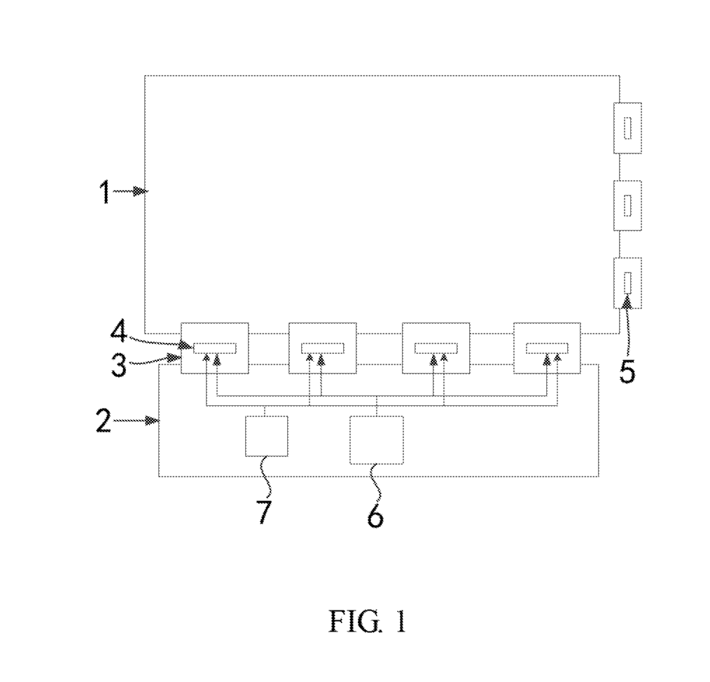

In the figures: FIG. 1: 1. array substrate; 2. timing control board; 3. flexible circuit board; 4. source driver IC; 5. gate driver IC; 6. timing controller; 7. power module;

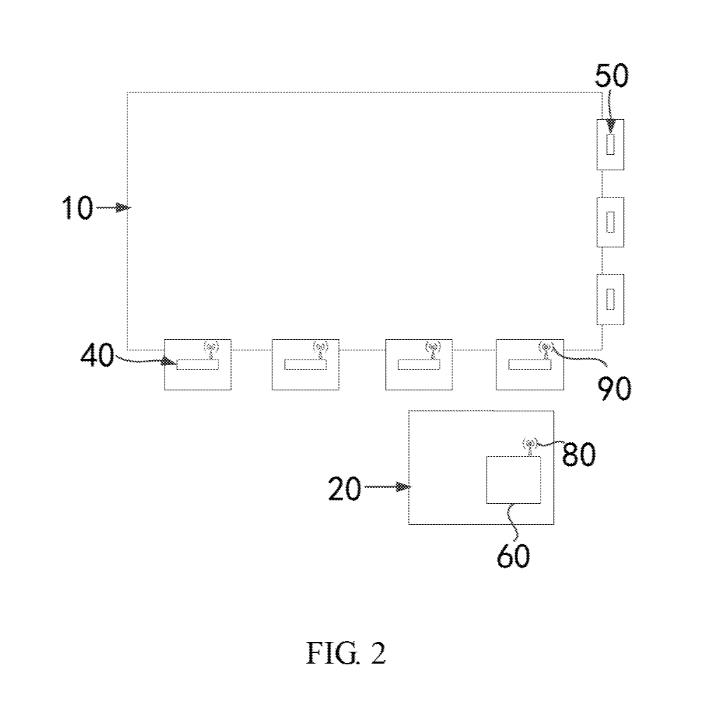

In the figures: FIG. 2 to FIG. 10: 10. array substrate; 20. timing control board; 30. flexible circuit board; 31. first flexible circuit board; 40. source driver IC; 41. first source driver IC; 42. second source driver IC; 43. third source driver IC; 50. gate driver IC; 60. timing controller; 70. power module; 71. first power line; 72. second power line; 73. third power line; 74. fourth power line; 75. fifth power line; 76. sixth power line; 77. seventh power line; 80. first wireless module; 90. second wireless module.

### DETAILED DESCRIPTION

Specific stricture and function details disclosed herein are only representative and are used for the purpose of describing exemplary embodiments of the present application. However, the present application may be specifically achieved in many alternative forms and shall not be interpreted to be only limited to the embodiments described herein.

It should be understood in the description of the present application that terms such as “central”, “horizontal”, “upper”, “lower”, “left”, “right”, “vertical”, “horizontal”, “top”, “bottom”, “inner”, “outer”, etc. indicate direction or position relationships shown based on the drawings, and are only intended to facilitate the description of the present application and the simplification of the description rather than to indicate or imply that the indicated device or element must have a specific direction or constructed and operated in a specific direction, and therefore, shall not be understood as a limitation to the present application. In addition, the terms such as “first” and “second” are only used for the purpose of description, rather than being understood to indicate or imply relative importance or hint the number of indicated technical features. Thus, the feature limited by “first” and “second” can explicitly or impliedly comprise one or more features. In the description of the present application the meaning of “a plurality of” is two or more unless otherwise specified. In addition the term “comprise” and any variant are intended to cover non-exclusive inclusion.

It should be noted in the description of the present application that, unless otherwise specifically regulated and defined, terms such as “installation,” “bonded,” and “bonding” shall be understood in broad sense, and for example, may refer to fixed bonding or detachable bonding or integral bonding, may refer to mechanical bonding or electrical bonding and may refer to direct bonding or indirect bonding through an intermediate medium or inner communication of two elements. For those of ordinary skill in the art, the meanings of the above terms in the present application may be understood according to concrete conditions.

The terms used herein are intended to merely describe concrete embodiments, not to limit the exemplary embodiments. Unless otherwise noted clearly in the context, singular forms “one” and “single” used herein are also intended to comprise plurals. It should also be understood that the terms “comprise” and/or “include” used herein specify the existence of stated features, integers, steps, operation, units and/or assemblies, not excluding the existence or addition of one or more other features, integers, steps, operation, units, assemblies and/or combinations of these.

The present application will be further described in detail below in combination with the drawings and preferred embodiments.

As shown in FIG. 1, specifically, the display panel comprises an array substrate 1, four flexible circuit boards 3 connected to the array substrate, source driver ICs 4 disposed on the flexible circuit boards 3, a timing control board 2 (or a printed circuit board) connected to the flexible circuit boards, a timing controller 6 disposed on the timing control board 2, and a power module 7, wherein a number of the source driver ICs 4 is also four. One source driver IC 4 is disposed on one flexible circuit board 3. The timing control board 2 is fixedly connected to the four flexible circuit boards directly. The four flexible circuit boards are spacedly arranged on one side of the array substrate 1. A signal generator 6 on the timing control board is electrically connected to the four source driver ICs respectively through the signal line to realize signal transmission. The power module on the timing control board is electrically connected to the four source driver ICs through the power line (an arrow is smaller than the signal line) for supplying power for the four source driver ICs. The signal line and the power line are disposed on the timing control board and penetrate through the flexible circuit boards to realize the bonding with the source driver ICs.

However, the timing control board is still large, and may also cause waste of the boards.

The display panel and the display apparatus of the embodiment are described below with reference to FIG. 2 to FIG. 10.

In combination with FIG. 1, in the prior art, the existing timing controller and power module are disposed on the timing control board, and the timing controller is electrically connected to all the source driver ICs through the signal line to realize signal transmission. The power module is electrically connected to all the source driver IC's through the power line, and the power line and the signal line are directly disposed on the timing control hoard. Because of this, the time control board has a large volume, causing not only the waste of the boards, but also increase of processing procedure.

Meanwhile, if the timing control board is too long and too large, serious expansion and extraction are often caused because the overlarge timing control board is damped when an LCD module (LCM) is connected to the flexible circuit boards and the timing control board. Therefore, normal alignment cannot be performed generally during butting, causing great inconvenience for production.

However, the present application discloses a display panel according to the above technical problem. As shown in FIG. 2 to FIG. 9, the display panel comprises:

an array substrate 10;

at least two source driver ICs 40 spacedly arranged on one side surface of the array substrate 10; and

a timing control board 20 disposed on the timing control board 20, wherein at least one of the source driver ICs 40 is wirelessly connected to the timing controller 60, and a length of the timing control board 40 is less than a maximum distance across all the source driver ICs 40.

When the timing control board in the display panel of the present application is electrically connected to or is in the signal transmission process with the source driver ICs, at least one of the source driver ICs is wirelessly connected to the tilting control board to realize wireless signal transmission. Because of this, fewer signal lines (part of the source driver ICs are connected to the timing control board through the signal line to realize signal transmission) or no signal line can be disposed on the timing control board. Thus, the size of the timing control board is reduced, so that a length of the timing control board is less than a maximum distance across all the source driver ICs, thereby ensuring that the timing control board can complete signal transmission without alignment with all the source driver ICs. The present application can not only save boards, but also facilitate the purchase and the design of circuits by engineers, and save production processes by reducing the size of the timing control board.

Meanwhile, the size of the timing control board is greatly reduced in the present application, and serious expansion and extraction due to the damped overlarge timing control board may not appear, thereby realizing normal alignment and normal fixed bonding of the timing control board.

Specifically, for example, if the number of the source driver ICs is two, then the timing control board can be wirelessly connected to two source driver ICs simultaneously; or the timing control board is wirelessly connected to one source driver IC, and is in wired bonding with the other source driver IC.

In another example, if the number of the source driver ICs is three, then the timing control board can be wirelessly connected to three source driver ICs simultaneously; or the timing control board is wirelessly connected to one source driver IC, and is in wired bonding with the other two source driver ICs; or the timing control board is wirelessly connected to two source driver ICs, and is in wired bonding with the other source driver IC.

In another example, if the number of the source driver ICs is four, then the timing control board can be wirelessly connected to four source driver ICs simultaneously; or the timing control board is wirelessly connected to one, two or three source driver ICs, and is in wired bonding with the remaining other source driver ICs. When the number of the source driver ICs is greater than four, the manner that all the source driver ICs are wirelessly bonded can be adopted, or the manner that only part of the source driver ICs are wirelessly bonded is adopted.

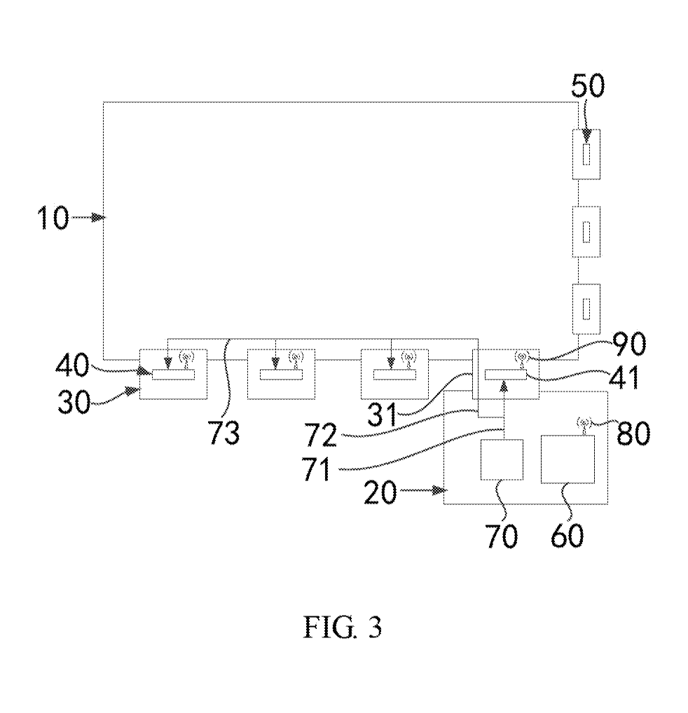

As shown in FIG. 2 and FIG. 3, the display panel in the embodiment of FIG. 2 and FIG. 3 comprises an array substrate 10, source driver ICs 40 and a timing control board 20. A number of the source driver IC's 40 is at least two (in the present embodiment, the number of the source driver ICs is four as an example for description. However, for those skilled in the art, the number of the source driver ICs in the present embodiment is not limited thereto). The at least two source driver ICs 40 are spacedly arranged on one side surface of the array substrate 10. A timing controller 60 is disposed on the timing control board 20. At least one of the source driver ICs 40 is wirelessly connected to the timing controller 60. A length of the timing control board 40 is less than a maximum distance across all the source driver ICs 40.

Specifically, the timing controller 60 is wirelessly connected to all the source driver ICs 40 directly. The timing controller 60 is wirelessly connected to all the source driver ICs 40 directly, so that the size of the timing control board 20 is greatly reduced without wiring on the timing control board 20 in a signal transmission process of the timing controller 60 with the source driver ICs 40. Because of this, the present embodiment can save the boards, facilitate the purchase and the design of circuits by engineers, and save production processes by greatly reducing the size of the timing control board 20. Meanwhile, serious expansion and extraction due to the damped overlarge timing control board may not appear, thereby realizing normal alignment and normal fixed bonding of the timing control board.

The display panel further comprises at least two flexible circuit boards spacedly arranged (similarly, the number of the flexible circuit boards in the present embodiment is also four). The flexible circuit boards 30 are fixedly bonded to the array substrate 10. One of the source driver ICs 40 is disposed on one of the flexible circuit boards 30. The flexible circuit board 30 comprises a first flexible circuit board 31; the source driver IC 30 comprises a first source driver IC 41. The first source driver IC 41 is disposed on the first flexible circuit board 31. The timing control board 20 is connected to the array substrate 10 through the first flexible circuit board 31. Compared with, the timing control board needs to be fixedly bonded to all the flexible circuit boards and the timing controller penetrates through all the flexible circuit boards and is connected to all the source driver ICs through the signal line, the present embodiment just has the timing control board 20 and the first flexible circuit board 31 to be fixedly bonded, thereby not only greatly reducing the size of the timing control board 20, but also greatly saving bonding between the timing control board 20 and the flexible circuit board 30, and also greatly saving time in practical processing and production.

In the present embodiment, it should be noted that the fixed bonding between the timing control board and the first flexible circuit board in the present embodiment is a preferred mode of the present embodiment. The timing control board in the present embodiment can be electrically connected to other source driver ICs.

In the present embodiment, a first wireless module 80 is disposed on the timing controller 60. The first wireless module is used for transmitting a wireless signal (such as mini-LVDS), correspondingly, four source driver ICs 40 are provided with the second wireless modules 90, and the second wireless modules 90 are used for receiving wireless signals (such as mini-LVDS) transmitted by the first wireless module. Because of this, the wireless bonding between the timing controller and the source driver ICs is realized, wherein the wireless bonding comprises but not limited to BLUETOOTH, WIFI, 2.4G radio, radio frequency (RF), and near field communication (NFC).

Further, the display panel further comprises a power module 70, wherein the power module 70 is electrically connected to the source driver IC 40 through the power line. Further, the power module 70 is disposed on the timing control board 20. The timing control board 20 is fixedly bonded to the first flexible circuit board 31 directly, and the power module 70 is disposed on the timing control board 20, to facilitate the electrical bonding with the first source driver IC 41 and other source driver ICs.

Specifically, the power line comprises a first power line 71, a second power line 72 and a third power line 73. The power module 70 is directly connected to the first source driver IC 41 through the first power line 71. A first end of the second power line 72 is connected to the power module 70, and a second end of the second power line 72 is connected to the third power line 73. The second power line 72 penetrates through the entire first flexible circuit board 31, and the third power line 73 is disposed on the array substrate 10, and is specifically disposed on the glass plate of the array substrate 10. The third power line 73 is connected to at least one of the source driver ICs 40, and as shown in FIG. 2, the third power line 73 is connected to three source driver ICs except for the first source driver IC. This is a specific manner as well as a preferred mode of the power module 70 is electrically connected to the source driver IC through the power line. The power module cannot directly realize electrical bonding with all the source drive ICs through the wiring of the timing control board, because the timing control board 20 is fixedly bonded to the first flexible circuit board 31, the first source drive IC 41 is disposed on the first flexible circuit board 31, and the power module 70 can be directly connected to the first source driver IC 41 through the first power line, and also because the timing control board is only fixedly bonded to the first flexible circuit board and not fixedly bonded to all the flexible circuit boards. In the present embodiment, the third power line is disposed on the glass plate of the array substrate 10 to realize electrical bonding with the source driver IC, and is connected to the second power line for communication relationship of the entire electrical bonding. The third power line occupies a small space, and may not produce large parasitic capacitance and resistance. Therefore, the third power line can be disposed on the array substrate. Thus, the present embodiment not only has no signal line and greatly reduces the size of the timing control board, but also installs part of the power line on the array substrate. Because of this, the arrangement of the power line on the timing control board is further reduced, and the size of the timing control board is further reduced.

However, it should be noted that the electrical bonding between the power module and the source driver ICs realized by the first power line, the second power line and the third power line is a preferred manner of an embodiment of the present application, and an electrical bonding relationship between the power module and the source driver ICs in the present embodiment is not limited thereto.

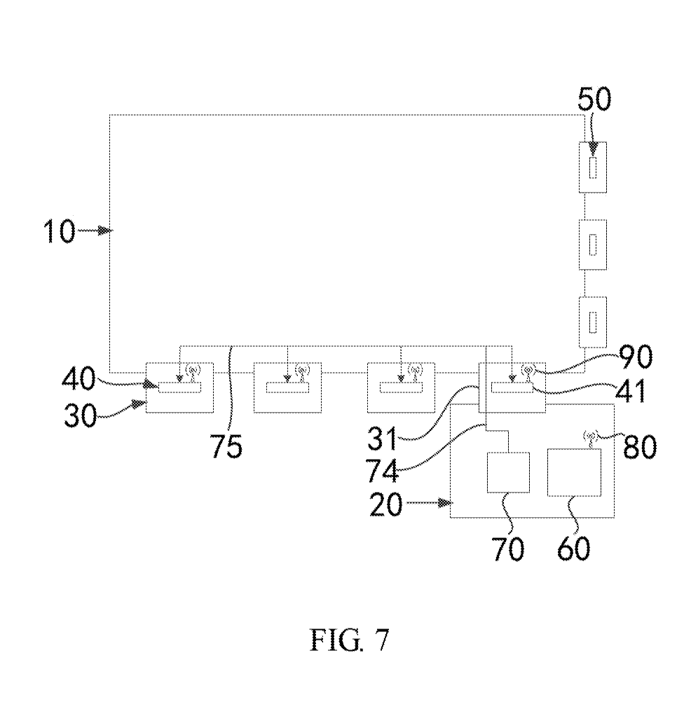

Example 1: As shown in FIG. 7, the power line comprises a fourth power line 74 and a fifth power line 75. A first end of the fourth power line 74 is connected to the power module 70, and a second end of the fourth power line 74 is connected to the fifth power line 75. The fourth power line 74 penetrates through the entire first flexible circuit board 31 and reaches the array substrate 10. The fifth power line 75 is disposed on the ay substrate 10, and is specifically disposed on the glass plate of the array substrate 10. The fifth power line 75 is connected to all the source driver ICs 40, i.e., the fifth power line 75 is electrically connected to four source driver ICs. This is another specific manner of the power module 70 is electrically connected to the source driver IC 40. Specifically, one end of the fourth power line is led out of the power module, then the fourth power line penetrates through the entire first flexible circuit board and is connected to the fifth power line on the array substrate, and the fifth power line is electrically connected to all the source driver ICs. Because of this, the power module realizes an electrical bonding relationship with all the source driver ICs. Compared with the electrical bonding realized by the first power line, the second power line and the third power line, the present application occupies more array substrate space through the fourth power line and the fifth power line. However, the wiring on the timing control board is further reduced, and the size of the timing control board is further reduced.

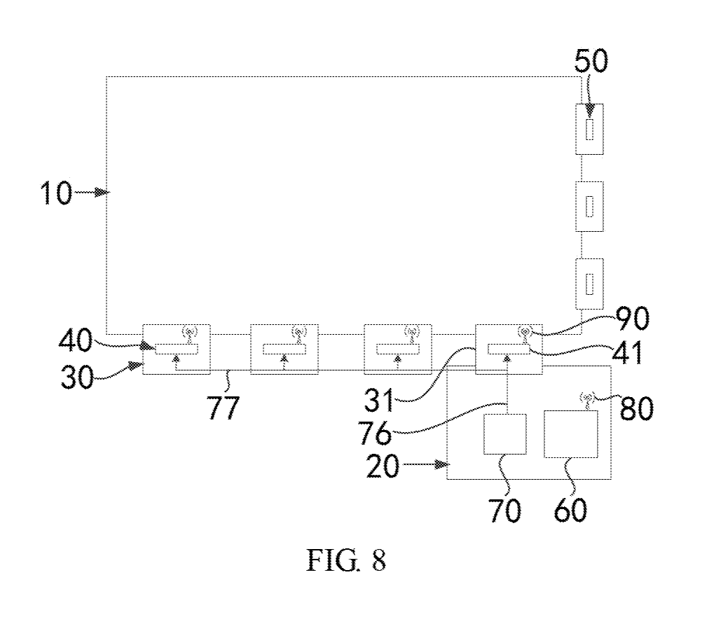

Example 2: As shown in FIG. 8, the power line comprises a sixth power line 76 and a seventh power line 77. The power module 70 is electrically connected to the first source driver IC 41 directly through the sixth power line 76, and he power module 70 is electrically connected to at least one of the source driver ICs through the seventh power line 77, i.e., the seventh power line is electrically connected to the remaining three source driver ICs except for the first source driver IC. Specifically, the sixth power line 76 and the seventh power line 77 are not disposed on the array substrate 10, thereby saving space of the array substrate.

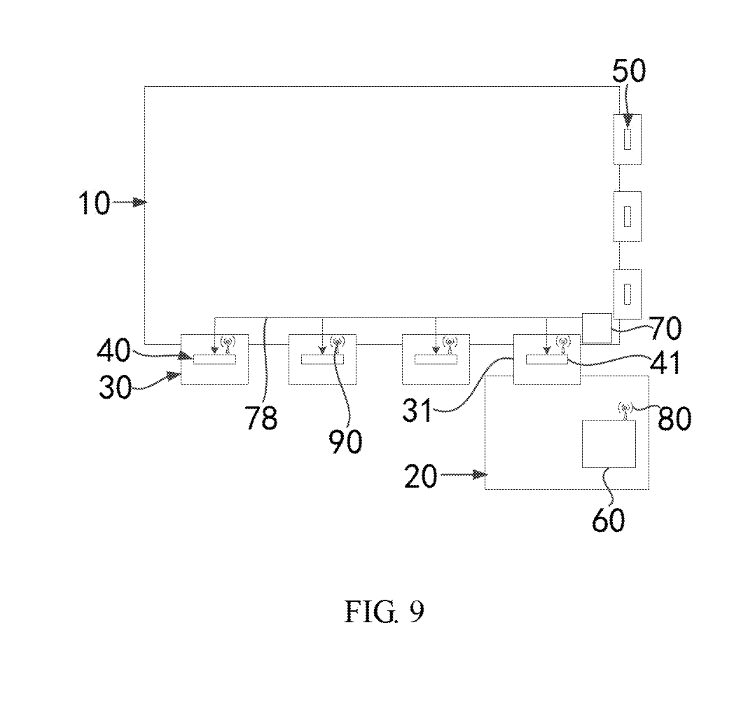

Example 3: As shown in FIG. 9, because the timing controller 60 on the timing control board 20 is wirelessly connected to all the source driver ICs 40, installation and fixing scope of the timing control board 20 is very wide. Thus, the power module 70 may not be disposed on the timing control board 20. For example, the power module 70 is directly disposed on a glass plate of the array substrate 10, and the power liner is also disposed on the glass plate of the array substrate. Because of this, the power module 70 can be electrically connected to the source driver ICs 40 directly through the power line on the array substrate 10.

The above contents are the specific illustrations of several manners for realizing the electrical bonding between the power module and the source driver ICs. However, it should be noted that the manner for realizing the electrical bonding between the power module and the source driver ICs in an embodiment of the present application is not limited thereto.

In an embodiment of the present application, the power module 70 may be a DCDC chip, and an external power supply is converted into a working power supply of the source driver ICs 40 through DCDC.

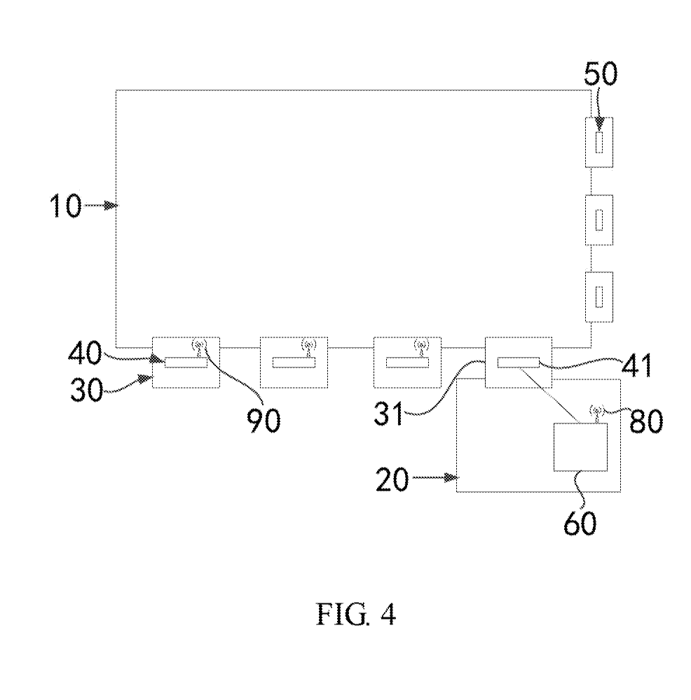

As shown in FIG. 4, the display panel in the present embodiment of FIG. 4 comprises an array substrate 10, source driver ICs 40, and a timing control board 20. The number of the source driver ICs 40 is at least two (in the present embodiment, the number of the source driver ICs is four as an example for description. However, for those skilled in the art, the number of the source driver ICs in the present embodiment is not limited thereto). The at least two source driver ICs 40 are spacedly arranged on one side surface of the array substrate 10, a timing controller 60 is disposed on the timing control board 20, and at least one of the source driver ICs 40 is wirelessly connected to the timing controller 60, wherein a length of the timing control board 40 is less than a maximum distance across all the source driver ICs 40.

Specifically, the display panel further comprises at least two flexible circuit boards spacedly arranged (similarly, the number of the flexible circuit boards in the present embodiment is also four). The flexible circuit boards 30 are fixedly bonded to the array substrate 10, one of the source driver ICs 40 is disposed, on one of the flexible circuit boards 30, and the flexible circuit board 30 comprises a first flexible circuit board 3. The wherein source driver IC 40 comprises a first source driver IC 41. The timing control board 20 is electrically connected to the first source driver IC 41, and the first source driver IC 41 is positioned between the array substrate 10 and the timing control board 20. Specifically, the first source driver IC 41 is disposed on the first flexible circuit board 31, and the timing control board 20 is connected to the array substrate 10 through the first flexible circuit board 31, wherein the timing controller 60 is connected to the first source driver IC 41 through the signal line. Because the first source driver IC 41 is positioned between the timing control board and the array substrate and the timing control board is close to the first source driver IC, bonding between the timing controller and the first source driver IC through the signal line is convenient without any additional increasing the size of the timing control board. This is another manner of the timing controller is electrically connected to the source driver IC in the present application. Compared with the wireless bonding between the timing controller and all the source driver ICs, the present application adds the signal line for the timing control board.

Distinctive features between the embodiment of FIG. 4 and the embodiment of FIG. 2 and FIG. 3 are that the timing controller 60 is connected to the first source driver IC 41 through the signal line to realize signal transmission, and the timing controller 60 is wirelessly connected to other three source driver ICs except for the first source driver IC. The specific wireless bonding manner of the embodiment of FIG. 4 is the same as that of the embodiment of FIG. 2 to FIG. 3, which can be found in the embodiment of FIG. 2 to FIG. 3 in combination with FIG. 7 to FIG. 9, and will not be described in detail herein. In addition, the power module of the display panel in the embodiment of FIG 4 is the same as that in the embodiment of FIG. 2 to FIG. 3, which can be found in the embodiment of FIG. 2 to FIG. 3 in combination with FIG. 7 to FIG. 9, and will not be described in detail herein.

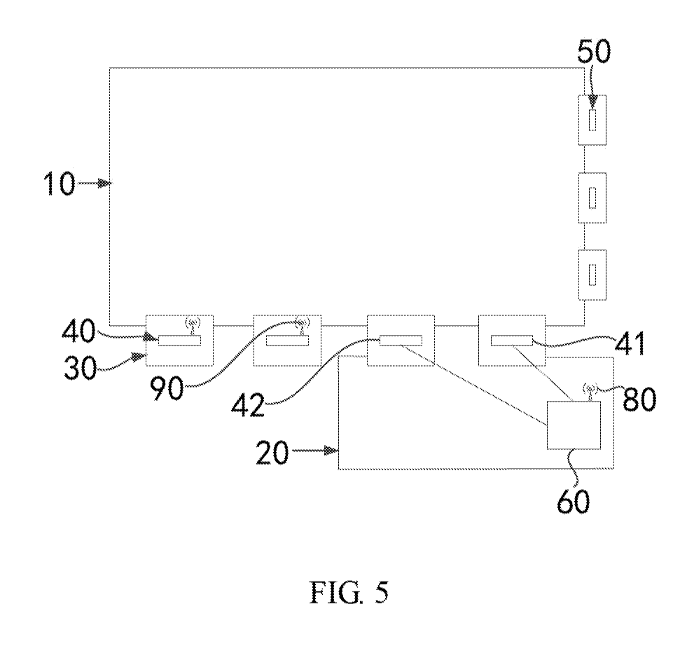

As shown in FIG. 5, the display panel in the embodiment of FIG. 5 comprises an array substrate 10, source driver ICs 40, and a timing control board 20. The number of the source driver ICs 40 is at least two (in the present embodiment, the number of the source driver ICs is four as an example for description. However, for those skilled in the art, the number of the source driver ICs in the present embodiment is not limited thereto). The at least two source driver ICs 40 are spacedly arranged on one side surface of the array substrate 10, a timing controller 60 is disposed on the timing control board 20, and at least one of the source driver ICs 40 is wirelessly connected to the timing controller 60, wherein a length of the timing control board 40 is less than a maximum distance across all the source driver ICs 40.

Specifically, the display panel further comprises at least two flexible circuit boards spacedly arranged (similarly, the number of the flexible circuit boards in the present embodiment is also four). The flexible circuit boards 30 are fixedly bonded to the array substrate 10, and one of the source driver ICs 40 is disposed on one of the flexible circuit boards 30. The flexible circuit board 30 comprises a first flexible circuit board 31, the source driver IC 40 comprises a first source driver IC 41 and a second source driver IC 42, and the timing control board 20 is electrically connected to the first source driver IC 41 and the second source driver IC. The first source driver IC and the second source driver IC are positioned between the timing control board and the array substrate. Specifically, the first source driver IC is disposed on the first flexible circuit board, the second source driver IC is disposed on one flexible circuit board, and the timing, control board is fixedly bonded to the array substrate through two adjacent flexible circuit boards, wherein the timing control board is coupled to the first source driver through the first signal line, and the timing control board is coupled to the second source driver through the second signal line. Because the first source driver IC and the second source drive IC are positioned between the timing control board and the array substrate, and the timing control board is close to the first source driver IC and the second source driver IC, bonding of the timing controller with the first source driver IC and the second source driver IC through the first signal line and the second signal line is convenient without any additional increasing the size of the timing control board. This is another manner of the timing controller is electrically connected to the source driver IC in the present application. Compared with the wireless bonding between the timing controller and all the source driver ICs, the present application adds the signal line for the timing control board.

Distinctive features between the embodiment of FIG. 5 and the embodiment of FIG. 2 and FIG. 3 are that the timing controller 60 is connected to the first source driver IC 41 and the second source driver IC 42 through the first signal line and the second signal line to realize signal transmission, and the timing controller 60 is wirelessly connected to other two source driver ICs except for the first source driver IC and the second source driver IC. The specific wireless bonding manner of the embodiment of FIG. 4 is the same as that of the embodiment of FIG. 2 to FIG. 1, which can be found in the embodiment of FIG. 2 to FIG. 3 in combination with FIG. 7 to FIG. 9, and will not be described in detail herein. In addition, the power module of the display panel in the embodiment of FIG. 4 is the same as that in the embodiment of FIG. 2 to FIG. 3, which can be found in the embodiment of FIG. 2 to FIG. 3 in combination with FIG. 7 to FIG. 9, and will not be described in detail herein.

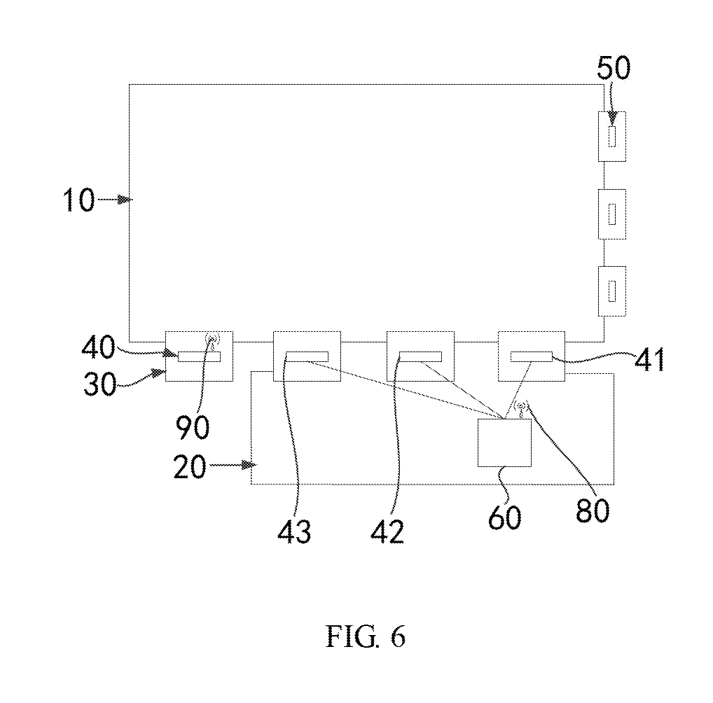

As shown in FIG. 6, the number of the source driver ICs in the embodiment of FIG. 6 is also four as an example for description. The differences between the embodiment of FIG. 6 and the embodiment of FIG. 2 and FIG. 3 are that the timing controller only realizes wireless bonding with one source driver IC 40, while the timing controller is respectively connected to the first source driver IC 41, the second source driver IC 42 and the third source driver IC 43 through the signal line to realize signal transmission. Similarly compared with the prior art, the present embodiment also reduces the arrangement of the signal line, and also reduces the size of the timing control board. The specific wireless bonding manner of the embodiment Of FIG. 6 is the same as that of the embodiment of FIG. 2 to FIG. 3, which can be found in the embodiment of FIG. 2 to FIG. 3 in combination with FIG. 7 to FIG. 9 and will not be described in detail herein. In addition, the power module of the display panel in the embodiment of FIG. 6 is the same as that in the embodiment of FIG. 2 to FIG. 3, which can be found in the embodiment of FIG. 2 to FIG. 3 in combination with FIG. 7 to FIG. 9, and will not be described in detail herein.

However, it should be noted that the number of the source driver ICs in the above embodiments of the present application is only four as an example for description. Of course, when the number of the source driver ICs is five or more, the timing controller can also realize wireless bonding with any one or more of the source driver ICs.

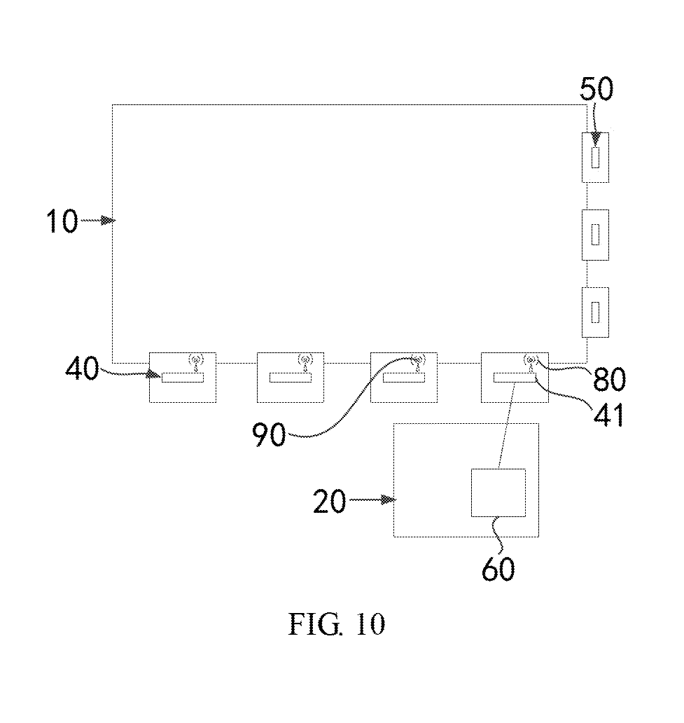

In addition, in the above embodiments of the present application, in the signal transmission process of the timing controller and the source driver ICs, other manners can also be adopted. As shown in FIG. 10, the timing controller 60 is connected to the first source driver IC 41 directly through the signal line to realize signal transmission. Meanwhile, the timing controller controls to package and transmit signals of other three source driver ICs except for the first source driver IC into the first source driver IC, and the first source driver IC wirelessly transmits the received packaged signals to the remaining three source driver ICs. Because of this, the present embodiment also reduces arrangement of the signal line on the timing control board, and also reduces the size of the timing control board. Specifically, as shown in FIG. 10, the timing controller 60 is disposed on the timing control board 20, the timing controller 60 is directly coupled to the first source driver IC 41 through the signal line, and a signal for controlling all the source driver ICs is transmitted to the first source driver IC 41. However, the first source driver IC 41 wirelessly transmits remaining signals out through the first wireless module 80 electrically connected to the first source driver IC 41, and the remaining three source driver ICs 40 receive the signals through the second wireless module 90. Because of this, signal transmission is completed.

The present application further discloses a display apparatus. The above display apparatus comprises the display panel and the backlight module in the above embodiment, wherein in the above display panel, the display panels in the embodiments of FIG. 2 to FIG. 10 can be seen and will not be repeated herein one by one, wherein the display apparatus in the present embodiment may be an LCD apparatus or other display apparatuses. When the display apparatus is the LCD apparatus, the backlight module may be a light source used for supplying sufficient brightness and uniformly distributed light sources. The backlight module in the present embodiment may be a front-light type, or a backlit type. It should be noted that the backlight module in the present embodiment is not limited thereto.

The above contents are further detailed descriptions of the present application in combination with specific preferred embodiments. However, the concrete implementation of the present application shall not be considered to be only limited to these descriptions. For those ordinary skilled in the art to which the present application belongs, several simple deductions or replacements may he made without departing from the conception of the present application, all of which shall be considered to belong to the protection scope of the present application.

1. A display panel, comprising:
an array substrate;
at least two source driver integrated circuits (ICs) spacedly arranged on one side surface of the array substrate; and
a timing control board disposed on the timing control board, wherein at least one of the source driver ICs is wirelessly connected to the timing controller, and a length of the timing control board is less than a maximum distance across all the source driver ICs.

2. The display panel according to claim 1, wherein the timing controller wirelessly connected to all the source driver ICs directly.

3. The display panel according to claim 1, wherein the display panel further comprises at least two flexible circuit boards spacedly arranged; and the two flexible circuit boards are fixedly bonded to the array substrate; and one of the source driver ICs is disposed on one of the flexible circuit boards;
wherein the flexible circuit board comprises a first flexible circuit board; and the source driver IC comprises a first source driver IC; and the first source driver IC is disposed on the first flexible circuit board, and the timing control board is coupled to the array substrate through the first flexible circuit board.

4. The display panel according to claim 3, wherein the display panel further comprises a power module electrically connected to the source driver IC through a power line.

5. The display panel according to claim 4, wherein the power module is disposed on the timing control board.

6. The display panel according to claim 5, wherein the power line comprises a first power line, a second power line and a third power line;
wherein the power module is directly connected to the first source driver IC through the first power line;
wherein a first end of the second power line is connected to the power module, and a second end of the second power line is connected to the third power line; and the second power line penetrates through the first flexible circuit board;
wherein the third power line is disposed on the array substrate, and the third power line is connected to at least one of the source driver ICs.

7. The display panel according to claim 5, wherein the power line comprises a fourth power line and a fifth power line;
wherein a first end of the fourth power line is connected to the power module, and a second end of the fourth power line is connected to the fifth power line; and the fourth power line penetrates through the first flexible circuit board;
wherein the fifth power line is disposed on the array substrate, and the fifth power line is connected to all the source driver ICs.

8. The display panel according to claim 1, wherein the source driver IC comprises a first source driver IC; and the timing control board is electrically connected to the first source driver IC; and the first source driver IC is positioned between the array substrate and the timing control board, and the timing controller is coupled to the first source driver IC through a signal line.

9. The display panel according to claim 1, wherein the source driver IC comprises a first source driver IC and a second source driver IC;
wherein the timing control board is electrically connected to the first source driver IC and the second source driver IC; and the first source driver IC and the second source driver IC are positioned between the timing control board and the array substrate;
wherein the timing control board is coupled to the first source driver IC through a first signal line, and the timing control board is coupled to the second source driver IC through a second signal line.

10. A display apparatus, comprising a display panel, wherein the display panel comprises:
an array substrate;
at least two source driver ICs spacedly arranged on one side surface of the array substrate; and
a timing control board disposed on the timing control board, wherein at least one of the source driver ICs is wirelessly connected to the timing controller, and a length of the timing control board is less than a maximum distance across all the source driver ICs.

11. The display apparatus according to claim 10, wherein the timing controller is wirelessly connected to all the source driver ICs directly.

12. The display apparatus according to claim 10, wherein the display panel further comprises at least two flexible circuit boards spacedly arranged; and the two flexible circuit boards are fixedly bonded to the array substrate; and one of the source driver ICs is disposed on one of the flexible circuit boards; and the flexible circuit board comprises a first flexible circuit board;
wherein the source driver ICs comprises a first source driver IC; and the first source driver IC is disposed on the first flexible circuit board, and the timing control board is coupled to the array substrate through the first flexible circuit board.

13. The display apparatus according to claim 12, wherein the display panel further comprises a power module electrically connected to the source driver IC through a power line.

14. The display apparatus according to claim 13, wherein the power module is disposed on the timing control board.

15. The display apparatus according to claim 14, wherein the power line comprises a first power line, a second power line and a third power line;
wherein the power module is directly connected to the first source driver through the first power line;
wherein a first end of the second power line is connected to the power module, and a second end of the second power line is connected to the third power line; and the second power line penetrates through the first flexible circuit board;
wherein the third power line is disposed on the array substrate, and the third power line is connected to at least one of the source driver ICs.

16. The display apparatus according to claim 14, wherein the power line comprises a fourth power line and a fifth power line;
wherein a first end of the fourth power line is connected to the power module, and a second end of the fourth power line is connected to the fifth power line; and the fourth power line penetrates through the first flexible circuit board; and
wherein the fifth power line is disposed on the array substrate, and the fifth power line is connected to all the source driver ICs.

17. The display apparatus according to claim 1, wherein the source driver IC comprises a first source driver IC;
wherein the timing control board is electrically connected to the first source driver IC; and the first source driver IC is positioned between the array substrate and the timing control board, and the timing controller is coupled to the first source driver IC through a signal line.

18. The display apparatus according to claim 1, wherein the source driver IC comprises a first source driver IC and a second source driver IC;
wherein the tuning control board is electrically connected to the first source driver IC and the second source driver IC; and the first source driver IC and the second source driver IC are positioned between the timing control board and the array substrate;
wherein the timing control board is coupled to the first source driver IC through a first signal line, and the timing control board is coupled to the second source driver IC through a second signal line.
